(19) United States
(12) Patent Application Publication
(10) Pub. No.: US 2007/0272296 A1
(43) Pub. Date: Nov. 29, 2007

(54) Tandem Solar Cell with a Shared Organic Electrode

(76) Inventors: Christoph Brabec, Linz (AT); Saulo Ruiz Moreno, Jerez (ES); Christoph Waldauf, Innsbruck (AT)

Correspondence Address: FISH & RICHARDSON PC, P.O. BOX 1022, MINNEAPOLIS, MN, 55440-1022, US

(21) Appl. No.: 10/558,878

(22) PCT Filed: May 26, 2004
(86) PCT No.: PCT/EP04/50914

§ 371 Date: Apr. 9, 2007

(30) Foreign Application Priority Data
Jun. 12, 2003 (DE) 103265473

(51) Int. Cl. H01L 31/00

(52) U.S. Cl. 136/255

(57) ABSTRACT

The invention relates to a solar cell comprising at least two photoactive layers. Solar cells or photovoltaic elements of this type are also called tandem solar cells or photovoltaic multicells. Tandem solar cells are comprised, in essence, of an optical and electrical series connection of two photoactive layers. The invention particularly relates to organic tandem solar cells comprising according to the invention at least one shared electrode disposed between two photovoltaically active layers and made substantially of organic material.

The present invention concerns a solar cell comprising at least two photoactive layers. Solar cells or photovoltaic elements of this type are also called tandem solar cells or photovoltaic multicells. Tandem solar cells are comprised, in essence, of an optical and electrical series connection of two photoactive layers. The present invention particularly relates to organic tandem solar cells.

Tandem solar cells per se are essentially known. Tandem solar cells are essentially comprised of a series circuit composed of two (half-) solar cells. The tandem solar cells described herein constitute a mechanical, optical and electrical series connection of two solar cells. This results in an increased open-circuit voltage, since the individual voltages of the (half-) solar cells are cumulative. Tandem solar cells have a unique feature in the form of a shared electrode between the two solar cells, at which the two types of charge carriers of the one and the other solar cell recombine. If this electrode is prepared by means of a metallic layer, the light may be reflected by this metallic layer, leading to reflection losses and thus to power loss in the second cell.

Such tandem photovoltaic devices are known, for example, from DE 693 30 835 T2. However, DE 693 30 835 T2 is limited in its disclosure to p- and n-doped semiconductor material and does not disclose organic photovoltaic devices of any kind. One way of constructing the shared electrode differently in order to reduce reflection losses is specified in the article “High photovoltage multiple-heterojunction organic solar cells incorporating interfacial metallic nanoclusters,” in Applied Physics Letters, Vol. 80, No. 9, pp. 1667-1669 (Mar. 4, 2002).

As the title of the article suggests, it is proposed to replace the shared electrode, which is conventionally implemented as a continuous metallic layer, with individual, distributed, metallic nanoclusters. That is, the article proceeds from the basic idea of replacing an electrode that conducts over its entire area with individual, essentially punctiform, conductive junctions. This idea seems to be an outgrowth of the lattice-shaped electrodes used on the sides of conventional solar cells facing the incident light. Since the shared electrode does not have to dissipate the charges, but only conduct them to the next layer, an arrangement of essentially punctiform conductors is a solution that affords the lowest index of reflection for metallic electrodes.

However, there are no known solutions that reduce the reflective index significantly in some other way.

It is therefore desirable to have a tandem solar cell in which the losses caused by the reflective index of the shared electrode are reduced.

It is further desirable to speed up and simplify and the production of tandem solar cells and to reduce the cost of said production.

According to one aspect, the present invention provides a photovoltaic tandem cell comprising at least two photoactive layers, two external electrodes and at least one shared electrode that connects the two photoactive layers to each other, which is characterized by at least one shared electrode made of a material that is processable from solution.

A material that can be processed from solution is less expensive to use than a material that must be deposited from the gas phase, for example.

The material that is processable from solution is preferably an organic material. In addition, it is electrically conductive by virtue of its intrinsic chemical structure or as a result of its composition or doping. The material for example accepts electrons from fullerenes and/or holes from polymers. This is best achieved with metals, and also with highly doped semiconductors having a small bandgap, doped semiconductors having a slightly larger bandgap, etc. The necessary semitransparency is achieved by making the layers very, very thin.

The term “external electrode” relates to the position of the electrode in relation to the photoactive layers and not in relation to the tandem solar cell as a whole. In the case of a solar cell that is applied to a nonconducting substrate, the “external electrode” can also lie between the photoactive layers of the solar cell and the substrate.

The number of photoactive layers in the tandem cell is arbitrary, since the invention can in principle be used on a tandem cell composed of any number of individual cells. Obviously, tandem cells composed of a great many individual layers do not seem to be feasible, owing to the available bandgaps of the respective individual photoactive layers and the spectral distribution of the incident light, together with the respective absorption rates.

A further requirement imposed on the shared electrode is that the electrical properties of the electrode be designed so that the recombination of positive charges with negative charges takes place preferably on or in the electrode.

In a preferred embodiment of the invention, the conductive organic material of the shared electrode comprises a polymer, particularly PEDOT, PANI and/or derivatives and/or mixtures thereof. PEDOT (poly-3,4-ethylenedioxythiophene) is a conductive polymer based on a heterocyclic thiophene that polymerizes by means of diether bridges. PEDOT can also be used as PEDOT:PSS. PEDOT:PSS is a PEDOT doped with polystyrene sulfonate.

In one embodiment, the photovoltaic cell includes an intermediate layer containing conductive nanoparticles (metallic or semiconductive in nature, e.g.: CdSe, CdTe, CIS, ZnO, Ag or Au nanoparticles, etc.) that can be processed from solution. One readily feasible option in this case is to incorporate the nanoparticles into a polymer matrix so they can be processed from solution.

In another preferred embodiment of the invention, the conductive organic material of the shared electrode comprises PANI (polyaniline). PANI and PEDOT are relatively comparable in terms of function in this context.

The inventive photovoltaic cell is preferably an organic photovoltaic cell. The semitransparent conductive layer of organic material can also, however, be used for inorganic tandem solar cells.

The present invention can also be used for photovoltaic compound tandem cells. A photovoltaic compound cell can, for example, be implemented as an inorganic solar cell comprising an organic solar cell contacted by means of an inventive shared, transparent and conductive electrode made of organic material. The total absorption of such a compound cell can be controlled at will.

According to another aspect, the present invention provides a method operative to produce a photovoltaic tandem cell comprising at least two photoactive layers, two external electrodes, and at least one shared electrode that connects two photoactive layers to each other, and characterized in that the shared electrode made of a conductive organic material is applied between the two photoactive layers. The use of a conductive layer made of an organic material makes it possible to apply the layer from a solution, representing a significant simplification and cost reduction compared to the otherwise standard vacuum-processed metal layers. The conductive semitransparent organic material used can also be printed on, in a solvent that does not attack, damage or dissolve the underlying semiconductor.

In a preferred embodiment of the invention, the method is characterized by the fact that at least one of the photoactive layers is applied from a solvent.

A further advantage deriving from the use of a conductive semitransparent organic material is that the layer of organic material is resistant to chemicals, from which the second semiconductor layer is applied. The first semiconductor layer is thereby protected, and a second semiconductor layer can be applied from a solvent that would attack, dissolve or destroy the semiconductor layer if a conventional intermediate electrode were used. Generally speaking, therefore, the semiconductor layers and the intermediate electrode can be fabricated without the use of vacuum processes. From a process management standpoint, this represents a significant improvement and a decrease in production costs.

The conductive semitransparent layer of organic material can also be applied by means of a vacuum process if the two adjacent layers are applied by a vacuum process during production. In this way, the entire production line for the tandem solar cell can be maintained under vacuum conditions, and it would then be impractical to perform this one work step in a normal atmosphere.

The term “organic material” herein encompasses all types of organic, metalorganic and/or inorganic synthetic materials, which are denoted in English, for example, by the term “plastics.” This includes all types of materials except semiconductors used for conventional diodes (germanium, silicon) and typical metallic conductors. Thus, no limitation is intended in the dogmatic sense to organic material as carbon-containing material, but rather, the widespread use of, for example, silicones is also contemplated. Furthermore, the term is not intended to imply any limitation with respect to molecular size, particularly to polymeric and/or oligomeric materials, but instead the use of “small molecules” is also feasible throughout.

The conductive semitransparent layer of organic material can also be, for example, a conjugated polymer that is not conductive, but is made conductive by the addition of conductive fillers. Other alternatives are organic materials that are applied by means of solvents and/or a vacuum process and that meet the set requirements with respect to conductivity and semitransparency.

One advantage of tandem solar cells is that the spectral absorption of the solar cell can be broadened substantially by using two solar cells connected in series. If, for example, semiconductors with different bandgaps (first semiconductor: large bandgap with absorption in the blue; second semiconductor: small bandgap with absorption in the red) are used for the two half-cells, the total absorption that results for the cell essentially represents a superposition of the individual or half-cells.

It should again be noted that this principle can also be extended to more than two half-cells, for example to three, four or more half-cells.

The invention is described below with reference to the appended drawing, in which

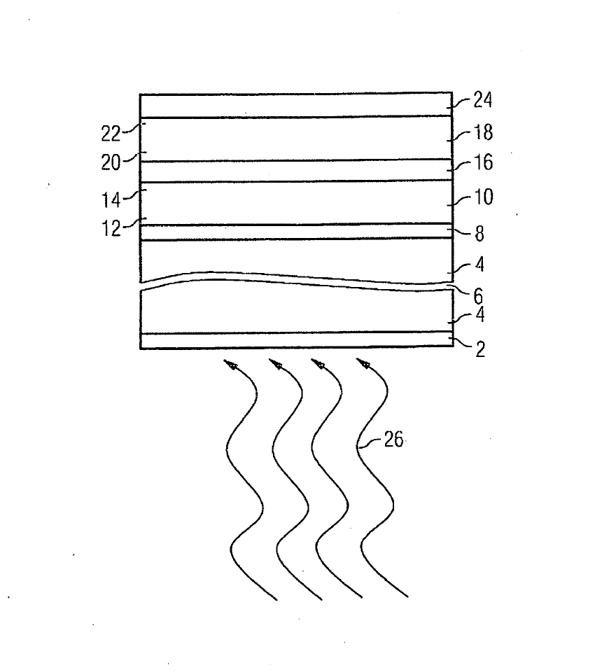

FIG. 1 is a sectional view through a solar cell according to one embodiment of the present invention.

FIG. 1 is a cross section through a tandem solar cell according to the present invention. The solar cell is applied to a carrier material or substrate 4. Substrate 4 can be made of organic material, for example flexible material or sheet, glass, plastic, a crystal or a similar material. Substrate 4 is depicted with a disconnect 6 to show that the thickness of the substrate 4 is immaterial to the present invention and can vary. The substrate merely serves to provide the solar cell with suitable mechanical strength and optionally with surface protection. The substrate is provided, on its side facing the incident light, with an antireflection coating 2 (or treatment) to reduce or prevent losses due to reflection.

The first layer 8 on the substrate constitutes one electrode 8 of the solar cell. It is basically immaterial to the invention whether the electrode is a cathode or an anode. Let us assume, without limitation, that light enters the depicted solar cell through substrate 4 from below. The first electrode 8 should therefore be made, for example, of Al, Cu, . . . , ITO (indium/tin oxide) or the like. It is to be noted that the electrode facing the incident light (electrode 8 in this case) is preferably transparent or semitransparent and/or has a lattice structure. Electrode 8 can also have a multilayer construction according to the prior art.

For the sake of simplicity, it will be assumed that electrode 8 disposed on substrate 4 is a cathode.

Electrode 8 is overlain by a first active layer 10. The composition of active layer 10 is substantially unimportant to the invention. Active layers ordinarily comprise one region with electron donors 14 and one region with electron acceptors 12, the two regions being connected to each other by a depletion layer. The charge carriers (electron-hole pairs) generated in the active layer by incident light are each drained separately into the adjacent layers.

The first active layer can be composed, for example, of a conventional monocrystalline, polycrystalline or amorphous semiconductor with a pn junction. However, the invention lends itself very particularly advantageously to use in organic solar cells for example comprising P3HT/PBCM, CuPc/PTCBI, ZNPC/C60 or a conjugated polymer component and a fullerene component.

In the case of the illustrated solar cell, the side 12 of active layer 10 directed toward the substrate is assigned to the electron acceptor and the side 14 facing away from the substrate to the electron donor.

Disposed over first active layer 10, on the side comprising the electron donors 14, is a shared organic electrode 16, made for example of a semitransparent conductive polymer. The further properties of the shared electrode 16, such as thickness and index of refraction, can be selected so that the shared electrode 16 forms a reflection layer between first active layer 10 and the next layer thereafter, i.e. second active layer 18. If the reflection properties of the electrode can be matched to a different spectral absorption region of the two active layers, this will have an additional positive effect on total absorption. If, for example, semiconductors with different bandgaps (first semiconductor: large bandgap with absorption in the blue; second semiconductor: small bandgap with absorption in the red) are used for the two half-cells, then the thickness of the semitransparent electrode can be adjusted so that a short-wave fraction of light is reflected back to the first photoactive layer, whereas a long-wave fraction is able to pass through the electrode to reach the second photoactive layer having the longer-wave absorption. The total absorption can also be influenced by imparting different thicknesses to the photoactive layers.

Semitransparent electrode 16 is followed by second photoactive layer 18. The composition of second active layer 18 is also basically immaterial to the present invention. The second active layer also comprises one region with electron donors 22 and one region with electron acceptors 20, the two regions being connected to each other by a depletion layer. The charge carriers (electron-hole pairs) generated in the active layer by incident light are each drained separately into the adjacent layers.

The second active layer can also be composed, for example, of a conventional monocrystalline, polycrystalline or amorphous semiconductor with a pn junction. However, the invention lends itself very particularly advantageously to use in organic solar cells for example comprising P3HT/PBCM, CuPc/PTCBI, ZNPC/C60 or a conjugated polymer component and a fullerene component. Naturally, combinations of conventional semiconductor materials can also be combined with organic semiconductors.

The second photoactive layer is overlain in turn by an external or connecting electrode. In the example given, this electrode 24 is an anode. The electrode material of the anode can in the present embodiment comprise, for example, Ag, Au, Al, Cu, . . . ITO or the like. Since the anode faces away from the incident light in the present example, it is not subject to restrictions of any kind with respect to thickness, transparency or any other restrictions. The anode can further be coated with a protective layer (not shown), for example a varnish.

The wavy arrows 26 indicate the direction of the incident light.

It goes without saying that the solar cell can also, conversely, be constructed on a for example non-transparent substrate 4 or directly on a conventional crystalline solar cell, in which case the light can then be incident from above. However, an “inverse” structure of this kind entails the disadvantage that the structures and layers facing the incident light are exposed to environmental influences such as atmospheric oxygen, dust and the like, which can rapidly damage the solar cell or make it unusable. In the case of an “inverse” structure, for example the antireflection coating 2 would have to be provided on the other side of the solar cell.

The invention can also be used with conventional monocrystalline or polycrystalline solar cells. Here again, the intermediate electrode 16 would be disposed between the active layers of the tandem solar cell.

Intermediate electrode 16 can be deposited either from the gas phase or from solution, thereby reducing the cost of processing and producing the intermediate layers.

The present invention concerns a solar cell comprising at least two photoactive layers. Solar cells of this kind are also called tandem solar cells or photovoltaic multicells. Tandem solar cells are comprised, in essence, of an optical and electrical series connection of two photoactive layers. The invention particularly relates to organic tandem solar cells comprising according to the invention at least one “shared” electrode disposed between two photovoltaically active layers and made substantially of organic material.

1. A photovoltaic tandem cell comprising at least two photoactive layers, two external electrodes and at least one shared electrode that is disposed between two respective adjacent photoactive layers and connects them to each other electrically and mechanically, characterized in that at least one shared electrode is made of a material that is applied from a solution.

2. The photovoltaic cell as in claim 1, characterized in that the material applied from solution is substantially an organic material.

3. The photovoltaic cell as in claim 1, characterized in that the material of the shared electrode comprises PEDOT.

4. The photovoltaic cell as in claim 1, characterized in that the material of the shared electrode comprises PANI.

5. The photovoltaic cell as in claim 1, characterized in that at least one of the at least two photoactive layers comprises conductive nanoparticles that are processable from a solution.

6. The photovoltaic cell as in claim 1, characterized in that at least one of the at least two photoactive layers comprises conductive nanoparticles that are mixed into a polymer matrix so that they are processable from a solution.

7. The photovoltaic cell as in claim 1, characterized in that said photovoltaic cell is an organic photovoltaic cell.

8. The photovoltaic cell as in claim 1, characterized in that the material is semitransparent.

9. A method of producing a photovoltaic tandem cell comprising two external electrodes and at least two photoactive layers, there being disposed between every two adjacent photoactive layers a shared electrode that connects them to each other mechanically and electrically, characterized in that at least one shared electrode is made of a conductive organic material and is applied to one of the at least two photoactive layers.

10. The method as in claim 9, characterized in that the at least one electrode is made of a conductive semitransparent organic material and is applied from a solution.

11. The method as in claim 9, characterized in that at least one of the photoactive layers is applied from a solution.
